(19) United States
(12) Patent Application Publication
(10) Pub. No.: US 2014/0284751 A1
(43) Pub. Date: Sep. 25, 2014

(54) Connection Structure of Wiring Cable and Connection Method of Wiring Cable

(71) Applicant: Kabushiki Kaisha Toshiba, Tokyo (JP)

(72) Inventor: Takatoshi Kamei, Oueme-shi (JP)

(73) Assignee: KABUSHIKI KAISHA TOSHIBA, Tokyo (JP)

(21) Appl. No.: 14/179,414

(22) Filed: Feb. 12, 2014

Related U.S. Application Data
(63) Continuation of application No. PCT/JP2013/001988, filed on Mar. 25, 2013.

(51) Int. Cl. H01L 27/146

(52) U.S. Cl. CPC H01L 27/14636; H01L 27/14683
USPC 257/443; 438/66

(57) ABSTRACT

To provide a connection structure of a wiring cable and a connection method of a wiring cable which enable the downsizing of a head part. The connection structure includes: a semiconductor chip having a plurality of imaging elements formed on a front surface and a plurality of connection pads formed on a rear surface; and a wiring cable in which a plurality of wires are integrally formed and from whose end surface the plural wires are exposed, wherein the plural connection pads of the semiconductor chip and the plural wires exposed from the end surface are connected.

### CROSS-REFERENCE TO RELATED APPLICATIONS

This application is a continuation of prior International Application No. PCT/JP2013/001988 filed on Mar. 25, 2013; the entire contents of all of which is incorporated herein by reference.

### FIELD

Embodiments described herein relate generally to a connection structure of a wiring cable and a connection method of a wiring cable.

### BACKGROUND

Imaging apparatuses include a head-separated imaging apparatus whose head part having an imaging element (for example, a CCD (Charge Coupled Device) image sensor or a CMOS (Complementary Metal Oxide Semiconductor) image sensor) is separated from a main body part which processes an image signal transmitted from the head part. In the head-separated imaging apparatus, the head part and the main body part are connected by a camera cable. Conventionally, the image sensor and the cable have been connected via a substrate, a FPC (flexible printed circuit), TAB (Tape Automated Bonding), and so on. However, recent years have seen a demand for further downsizing of the head part of the head-separated imaging apparatus.

The present invention was made to solve such a conventional problem, and its object is to provide a connection structure of a cable and a connection method of a cable which enable the downsizing of a head part.

A connection structure of a cable according to an embodiment includes: a semiconductor chip having a plurality of imaging elements formed on a front surface and a plurality of connection pads formed on a rear surface; and a wiring cable in which a plurality of wires are integrally formed and from whose end surface the plural wires are exposed, wherein the plural connection pads of the semiconductor chip and the plural wires exposed from the end surface are connected.

The present invention can provide a connection structure of a cable and a connection method of a cable which enable the downsizing of a head part.

### BRIEF DESCRIPTION OF THE DRAWINGS

FIG. 1 is a schematic diagram of an imaging apparatus according to an embodiment.

FIG. 2A and FIG. 2B are schematic views of an image sensor according to the embodiment.

FIG. 3 is a schematic view of a head part and a camera cable according to the embodiment.

FIG. 4A and FIG. 4B are schematic views illustrating examples of an alignment mark.

FIGS. 5A, 5B, 5C, and 5D are explanatory views of a connection method of the cable to the image sensor according to the embodiment.

### DETAILED DESCRIPTION

Hereinafter, an embodiment will be described in detail with reference to the drawings.

### Embodiment

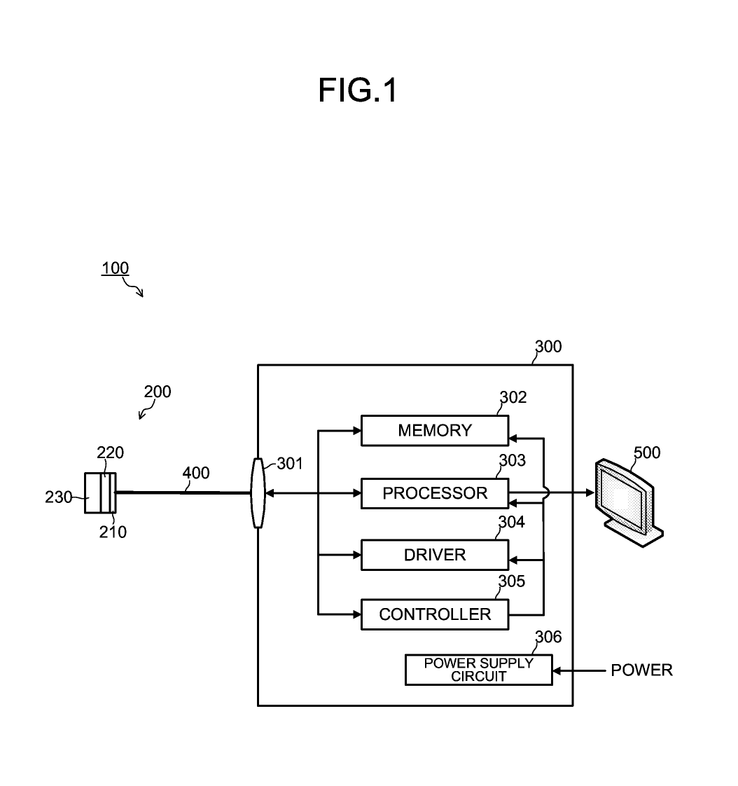

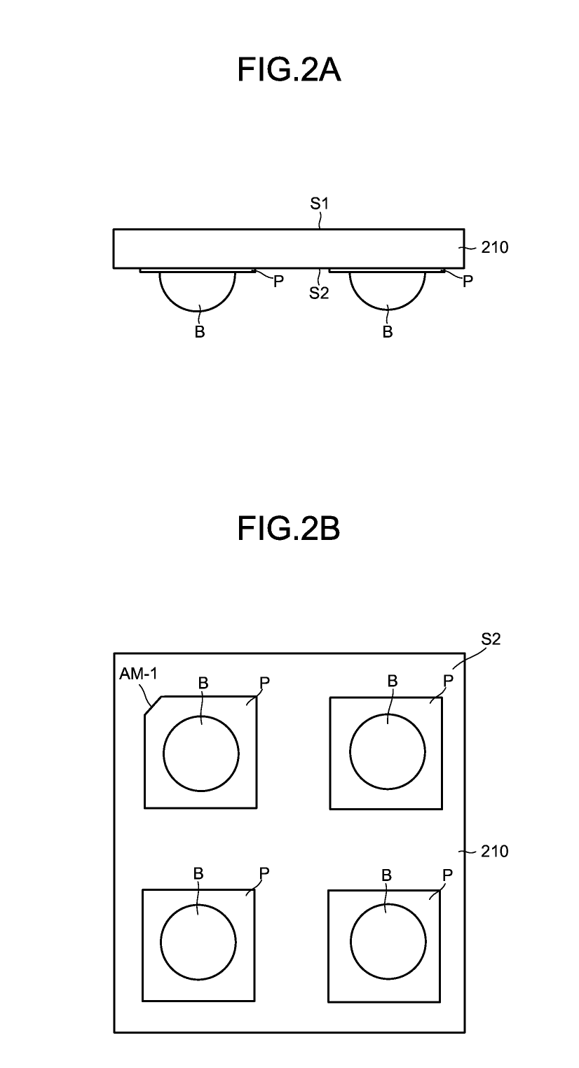

FIG. 1 is a schematic diagram of an imaging apparatus 100 according to the embodiment (hereinafter, referred to as the imaging apparatus 100). FIGS. 2A and 2B are schematic views of a head part 200 and a cable 400. The imaging apparatus 100 is, for example, an endoscope apparatus, and includes the head part 200, a CCU (Camera Control

Unit) 300 (hereinafter, referred to as the main body part 300), and the camera cable 400 (wiring cable) connecting the head part 200 and the main body part 300.

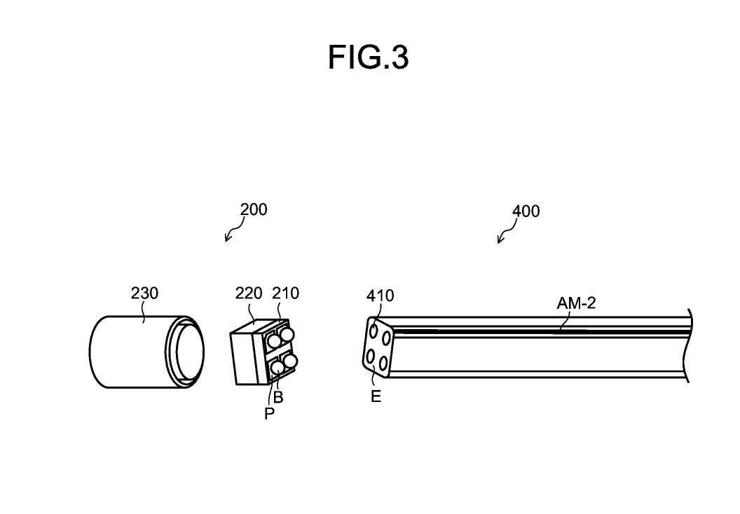

The head part 200 includes an image sensor 210 (semiconductor chip), a cover glass 220, and a lens body 230. A detailed structure of the head part 200 will be described with reference to FIGS. 2A and 2B and FIG. 3.

The main body part 300 includes an IF circuit 301, a memory 302, a processor 303, a driver 304, a controller 305, and a power supply circuit 306.

The IF circuit 301 is an interface for the transmission/receipt of control signals and data to/from the head part 200.

The memory 302 is a nonvolatile memory, and is, for example, a serial EEPROM (Electrically Erasable Programmable Read-Only Memory). In the memory 302, setting data (operation mode) of the head part 200 and correction data are stored.

The processor 303 is a processor for image processing. The processor 303 performs various kinds of corrections (for example, noise correction, white balance, y correction, and so on) of an image signal transmitted from the head part 200. The processor 303 outputs the corrected image signal to an external display device 500 (for example, a CRT (Cathode Ray Tube) or a liquid crystal monitor).

The driver 304 is a drive circuit of the image sensor 210. The driver 304 changes a drive method and a frame rate of the image sensor 210 based on the control from the controller 305. Further, the driver 304 outputs pulse signals (for example, pulse signals for vertical synchronization and horizontal synchronization (a transfer pulse signal, a reset gate pulse signal)) to the image sensor 210.

The controller 305 reads out the correction data and the setting data from the memory 302. The controller 305 controls the processor 303 and the driver 304 based on the read correction data and setting data.

The power supply circuit 306 is connected to an external power source. The power supply circuit 306 converts power from the external power source to a predetermined voltage to supply it to the constituent circuits (the IF circuit 301, the memory 302, the processor 303, the driver 304, the controller 305) of the main body part 300. Further, the power from the power supply circuit 306 is also supplied to the head part 200 via the camera cable 400.

### (Schematic Views of Image Sensor 210)

FIGS. 2A and 2B are schematic views of the image sensor 210. FIG. 2A is a side view of the image sensor 210. FIG. 2B is a plane view of a rear surface side of the image sensor 210. Hereinafter, the structure of the image sensor 210 will be described with reference to FIGS. 2A and 2B.

The image sensor 210 is a solid-state imaging element such as, for example, a CMOS (Complementary Metal Oxide Semiconductor) image sensor or a CCD (Charge Coupled Device) image sensor.

As illustrated in FIGS. 2A and 2B, the image sensor 210 has a rectangular shape. On a front surface S1 of the image sensor 210, an imaging element, a drive circuit of the imaging element, and so on, not shown, are formed. Further, on a rear surface S2 of the image sensor 210, a plurality of connection pads P having a rectangular shape are formed. On each of the connection pads P, a solder ball B is provided. The connection pads P are electrically connected to the imaging element, the drive circuit, and so on formed on the front surface S1, via not-shown through vias. Further, on the image sensor 210, an alignment mark AM-1 for positioning which is used when the image sensor 210 is connected to the camera cable 400 is provided. Note that, in the example illustrated in FIGS. 2A and 2B, one of corners of the connection pad P on the upper left in the drawing, out of the plural connection pads P formed on the rear surface S2 of the image sensor 210, is cut out, and this cutout serves as the alignment mark AM-1.

### (Structure of Head Part 200 and Cable 400)

FIG. 3 is a schematic view of the head part 200 and the cable 400. Note that in FIG. 3, the head part 200 is shown as an exploded schematic view. Hereinafter, the structure of the head part 200 and the cable 400 will be described with reference to FIG. 3.

As described with reference to FIG. 1, the head part 200 includes the image sensor 210, the cover glass 220, and the lens body 230. The cover glass 220 is a glass substrate protecting the front surface of the image sensor 210. The lens body 230 is provided on a front surface of the cover glass 220 (opposite the image sensor 210) and forms an image on the image sensor 210.

The camera cable 400 is, for example, a wiring cable in which a plurality of wires 410 are integrated by a resin R or the like by molding. The wires 410 of the camera cable 400 are buried in the resin R so as to correspond to positions of the connection pads P formed on the rear surface S2 of the image sensor 210, respectively. Further, an end surface E of the camera cable 400 on an image sensor 210 side is a surface cut by laser or the like and the wires 410 are exposed therefrom.

The end surface E (cut surface) of the camera cable 400 has a rectangular shape agreeing with the shape of the image sensor 210, and its lengthwise and breadthwise dimensions are also substantially equal to or smaller than those of the image sensor 210. Further, in the end surface E, an end surface of the resin R and end surfaces of the plural wires 410 are substantially flush with each other.

The plural wires 410 of the camera cable 400 are used for the transfer of a differential signal of data (image), for power supply, for GND, and so on, for instance.

Further, an alignment mark AM-2 for positioning which is used when the camera cable 400 is connected to the image sensor 210 is provided on the camera cable 400. In FIG. 3, part of the camera cable 400 is colored (given a different color) to serve as the alignment mark AM-2. Aligning the alignment mark AM-1 provided on the image sensor 210 and the alignment mark AM-2 provided on the camera cable 400 at the time of the connection results in the connection of the wires 410 of the camera cable 400 to the correct connection pads P respectively.

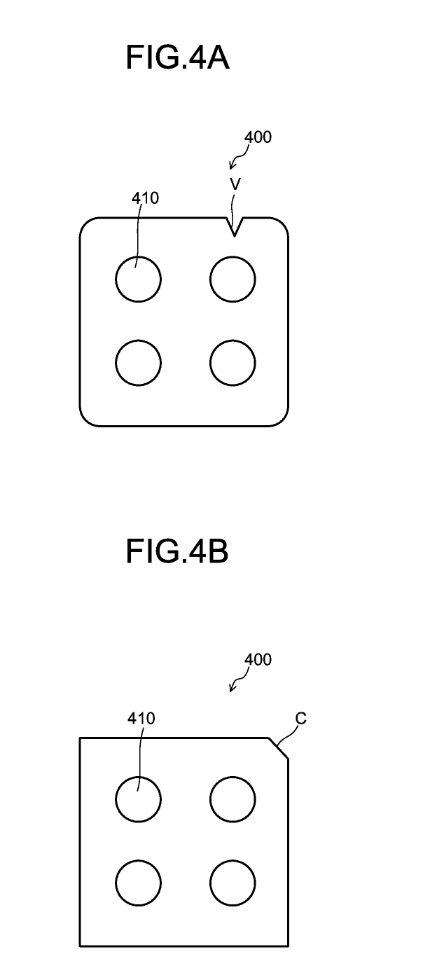

Note that the alignment mark AM-2 of the camera cable 400 is preferably provided along a longitudinal direction of the camera cable 400. The alignment mark AM-2, if being provided along the longitudinal direction of the camera cable 400, exists near a cut surface of the camera cable 400 at whichever position the camera cable 400 is cut. Incidentally, the alignment mark AM-2 may be, for example, a groove V provided in the camera cable 400 (refer to FIG. 4A) or a cutout C provided in only one side (refer to FIG. 4B).

### (Connection of Camera Cable 400 to Image Sensor 210)

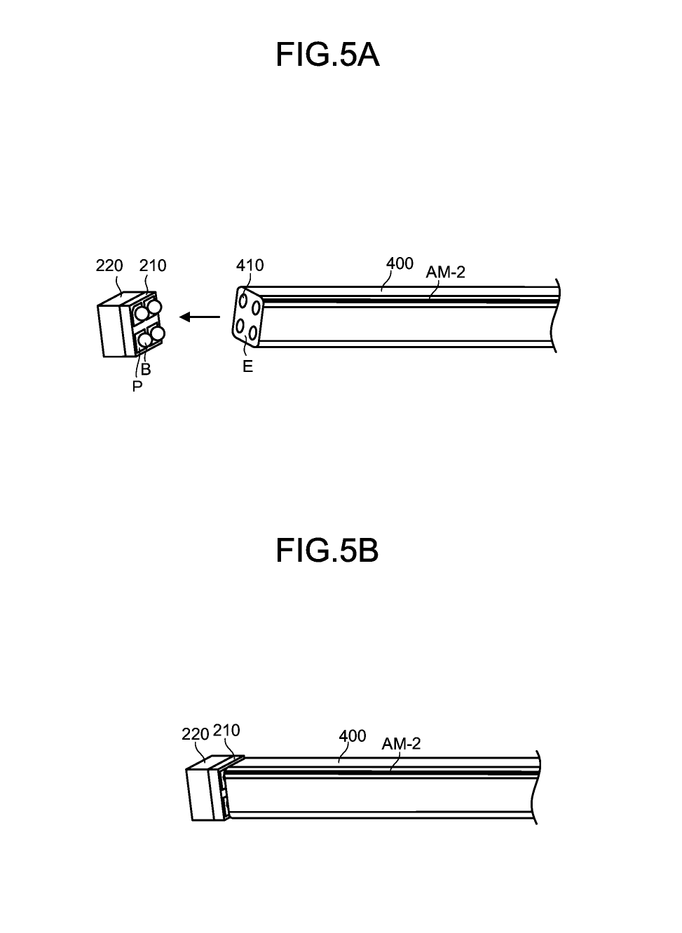

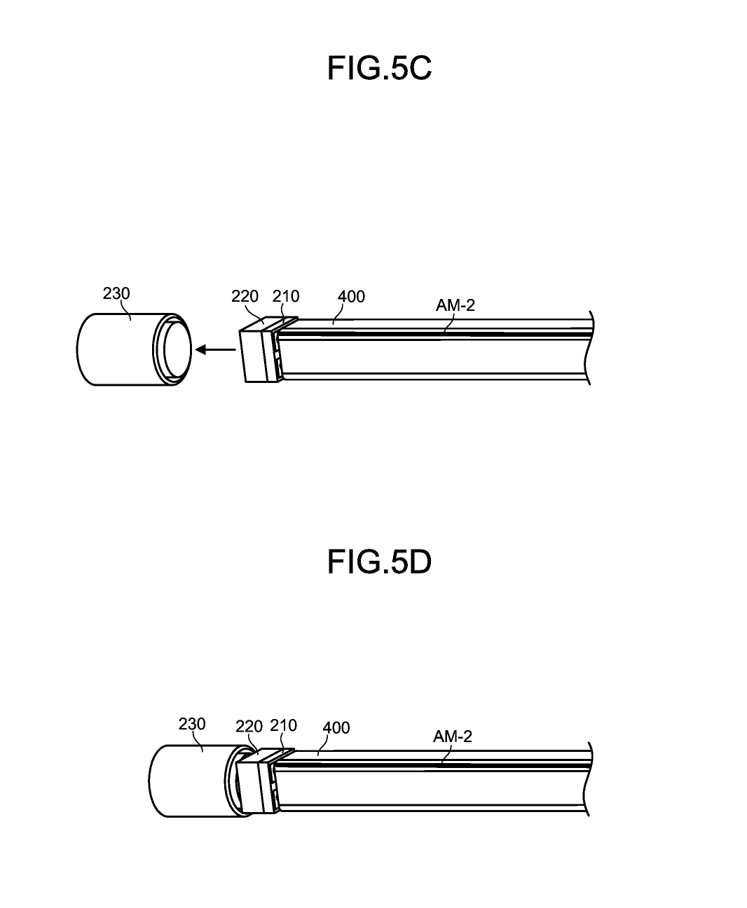

FIGS. 5A, 5B, 5C and 5D are views illustrating the procedure for connecting the camera cable 400 to the image sensor 210. The procedure (method) for connecting the camera cable 400 to the image sensor 210 will be described with reference FIGS. 5A, 5B, 5C and 5D.

First, the image sensor 210 and the camera cable 400 are prepared (refer to FIG. 5A). Note that it is assumed that the cover glass 220 for image sensor protection has already been bonded on the front surface of the image sensor 210.

Next, the alignment mark AM-1 of the image sensor 210 and the alignment mark AM-2 of the camera cable 400 are aligned with each other, and the end surface E of the camera cable 400 is pressed so that the wires 410 of the camera cable 400 abut on the solder balls B provided on the connection pads P formed on the rear surface of the image sensor 210. Here, the solder balls B have a semispherical shape. Therefore, even if the end surfaces of the wires 410 are slightly set back from the end surface E of the camera cable 400, it can be ensured that the end surfaces of the wires 410 and the solder balls B abut on each other.

Next, reflowing (heat treatment) of the solder balls B is performed to electrically join the connection pads P formed on the rear surface of the image sensor 210 and the wires 410 of the camera cable 400 (refer to FIG. 5B). Next, the lens body 230 is prepared (refer to FIG. 5C). Next, the lens body 230 is aligned by using a positioning jig or the like, and the lens body 230 is joined on the cover glass 220 by using an adhesive for optics (refer to FIG. 5D).

As described above, in this embodiment, at the time of the connection, the end surface of the camera cable 400 from which the plural wires 410 are exposed is pressed against the connection pads P formed on the rear surface S2 of the image sensor 210, and therefore, it is possible to easily connect the image sensor 210 and the camera cable 400.

Further, the connection pads P are formed on the rear surface of the image sensor 210, and the camera cable 400 is connected from the rear surface side of the image sensor 210 not via a substrate or the like but directly. Further, the shape and size of the cross section of the camera cable 400 are substantially equal to those of the image sensor 210. This can downsize the camera head 200. Further, since a casing covering the image sensor 210 is not provided, it is possible to further downsize the camera head 200.

Further, the solder balls B in the semispherical shape are provided on the connection pads P of the image sensor 210. Therefore, even if the end surfaces of the wires 410 are slightly set back from the end surface of the camera cable 400, it can be ensured that the end surfaces of the wires 410 and the solder ball B abut with each other. As a result, connection reliability of the image sensor 210 and the camera cable 400 is improved.

Further, only by the reflowing of the solder balls B, it is possible to connect the plural wires 410 of the camera cable 400 to the image sensor 210 at a time. Therefore, it is possible to easily connect the image sensor 210 and the camera cable 400. Further, since the number of man-hours necessary for the connection is small, the connection reliability further improves as compared with a case where the wires 410 are connected to the connection pads P of the image sensor 210 one by one.

Further, since the alignment marks AM-1, AM-2 are provided on the image sensor 210 and the camera cable 400 respectively, aligning the positions of the alignment mark AM-1 and the alignment mark AM-2 makes it possible to prevent the connection of the wrong combination of the connection pad P and the wire 410.

In the foregoing description, the case where the number of the connection pads P of the image sensor 210 is four is described, but the number of the connection pads P of the image sensor 210 is not limited to four. Further, the number of the wires 410 of the camera cable 400 is not limited to four either, and can be changed according to the number of the connection pads P of the image sensor 210. Further, the shape of the image sensor 210 is not limited to the rectangular shape and may be a circular shape or a cut circular shape. Further, the cross-sectional shape of the camera cable 400 is not limited to the rectangular shape either and may be a circular shape or a cut circular shape according to the shape of the image sensor 210.

### Other Embodiments

As described above, several embodiments of the present invention are described, but the above-described embodiments are presented as examples and are not intended to limit the scope of the invention. The above-described embodiments can be implemented in various other forms, and various omissions, substitutions, and modifications can be made without changing the spirit of the invention.

What is claimed is:

1. A connection structure of a wiring cable, comprising:
a semiconductor chip having a plurality of imaging elements formed on a front surface thereof and a plurality of connection pads formed on a rear surface thereof; and
a wiring cable integrally formed from a plurality of wires, the plurality of wires being exposed on an end surface of the wiring cable, the plurality of wires exposed on the end surface being connected with the plurality of connection pads of the semiconductor chip.

2. The connection structure of the wiring cable of claim 1,
wherein the plurality of wires are integrated in a fixed position in the wiring cable.

3. The connection structure of the wiring cable of claim 1,
wherein the plurality of connection pads and the plurality of wires are connected by solder.

4. The connection structure of the wiring cable of claim 1,
wherein the wiring cable comprises a first alignment mark thereon and the semiconductor chip comprises a second alignment mark thereon corresponding to the first alignment mark.

5. The connection structure of the wiring cable of claim 1,
wherein a cover glass is provided on the front surface of the semiconductor chip.

6. A connection method of a wiring cable, comprising:
preparing a semiconductor chip having a plurality of imaging elements formed on a front surface thereof and a plurality of connection pads formed on a rear surface thereof;
preparing a wiring cable integrally formed from a plurality of wires, the plurality of wires being exposed on an end surface of the wiring cable; and
pressing the plurality of wires exposed on the end surface to the plurality of connection pads so as to connect each other.

7. The connection method of the wiring cable of claim 6, further comprising
heating solder provided on the connection pads so as to connect the plurality of wires with the plurality of connection pads.

8. The connection method of the wiring cable of claim 6, further comprising:
providing a first alignment mark on the wiring cable and a second alignment mark on the semiconductor chip; and
aligning the first alignment mark with the second alignment mark before pressing the plurality of wires to the plurality of connection pads.

9. The connection method of the wiring cable of claim 6, further comprising
providing a cover glass on the front surface of the semiconductor chip.
